(19) United States
(12) Patent Application Publication
(10) Pub. No.: US 2016/0293707 A1
(43) Pub. Date: Oct. 6, 2016

(54) SEMICONDUCTOR DEVICE

(71) Applicant: GlobalWafers Co., Ltd., Hsinchu (TW)

(72) Inventors: Ming-Shien Hu, Taipei City (TW); Chien-Jen Sun, Hsinchu (TW); I-Ching Li, Hsinchu (TW); Wen-Ching Hsu, Hsinchu (TW)

(21) Appl. No.: 15/076,645

(22) Filed: Mar. 21, 2016

(30) Foreign Application Priority Data
Apr. 1, 2015 (TW) 104110647

(51) Int. Cl. H01L 29/15; H01L 29/207; H01L 29/778; H01L 29/20

(52) U.S. Cl. CPC H01L 29/157; H01L 29/2003; H01L 29/207; H01L 29/7785

(57) ABSTRACT

A semiconductor device includes a substrate, an initial layer, and a buffer stack structure. The initial layer is located on the substrate and includes aluminum nitride (AlN). The buffer stack structure is located on the initial layer and includes a plurality of base layers and at least one doped layer positioned between two adjacent base layers. Each of the base layers includes aluminum gallium nitride (AlGaN), and the doped layer includes AlGaN or boron aluminum gallium nitride (BAlGaN). In the buffer stack structure, concentrations of aluminum in the base layers gradually decrease, concentrations of gallium in the base layers gradually increase, the base layers do not contain carbon substantially, and dopants in the doped layer include carbon or iron.

### CROSS-REFERENCE TO RELATED APPLICATION

This application claims the priority benefit of Taiwan application serial no. 104110647, filed on Apr. 1, 2015. The entirety of the above-mentioned patent application is hereby incorporated by reference herein and made a part of this specification.

### TECHNICAL FIELD

The disclosure relates to a semiconductor device. More particularly, the disclosure relates to a semiconductor device having a buffer stack structure composed of base layers (aluminum gallium nitride, AlGaN) and a doped layer (AlGaN or boron aluminum gallium nitride, BAlGaN).

### DESCRIPTION OF RELATED ART

Nitride semiconductors are characterized by high electron saturation velocity and wide band gap and thus can be applied not only to light emitting semiconductor devices but also to compound semiconductor devices with high breakdown voltage and large power output. For instance, in a gallium nitride (GaN)-based high electron mobility transistor (HEMT), a GaN layer and an aluminum gallium nitride (AlGaN) layer are sequentially grown on the substrate in an epitaxial mariner. Here, the GaN layer serves as an electron transport layer, and the AlGaN layer acts as an electron supply layer. Since the lattice constant of AlGaN is different from that of GaN, strain may be generated in the AlGaN layer. Due to piezoelectric polarization, two-dimensional electronic gas (2 DEG) with high concentration is generated. Hence, the GaN-based HEMT is adapted to an apparatus with large output power.

According to the related art, dopants are continuously doped into the entire buffer layer made of AlGaN, which deteriorates crystallinity and roughness and leads to the issue of bowing of the entire semiconductor device.

### SUMMARY OF THE DISCLOSURE

In an embodiment of the disclosure, a semiconductor device that includes a substrate, an initial layer, and a buffer stack structure is provided. The initial layer is located on the substrate and includes aluminum nitride (AlN). The buffer stack structure is located on the initial layer and includes a plurality of base layers and at least one doped layer positioned between two adjacent base layers. Each of the base layers includes AlGaN, and the at least one doped layer includes AlGaN or boron aluminum gallium nitride (BAlGaN). In the buffer stack structure, concentrations of aluminum (Al) in the base layers gradually decrease, concentrations of gallium (Ga) in the base layers gradually increase, the base layers do not contain carbon substantially, and dopants in the at least one doped layer include carbon or iron.

In another embodiment of the disclosure, a semiconductor device that includes a substrate, an initial layer, and a plurality of buffer stack structures is provided. The initial layer is located on the substrate and includes AlN. The buffer stack structures are located on the initial layer. At least one of the buffer stack structures includes a first base layer, a first doped layer, and a second base layer. A concentration of Al of the first base layer and a concentration of Al of the second base layer are substantially the same, and the first doped layer is positioned between the first base layer and the second base layer. The first base layer and the second base layer include AlGaN, the first doped layer includes AlGaN or BAlGaN, dopants in the first doped layer include carbon or iron, and the first base layer and the second base layer do not contain carbon substantially.

In the disclosure, the doped layer with the dopants (carbon or iron) is inserted into the buffer stack structure of the semiconductor device, so as to reduce the conductivity of the buffer stack structure (i.e., enhance the degree of insulation of the buffer stack structure) and further raise the breakdown voltage of the semiconductor device effectively. According to the related art, dopants are continuously doped into the entire buffer layer made of AlGaN, which deteriorates crystallinity and roughness and leads to the issue of bowing of the entire semiconductor device. By contrast, in the semiconductor device provided herein, the base layers having no dopants are grown in an epitaxial manner above the doped layer with the dopants, so as to recover crystallinity and roughness of the epitaxy layer (the base layers has no dopants, and thus the crystallinity and roughness of the base layers are relatively enhanced). More specifically, in the disclosure, the base layers having no dopants is grown in an epitaxial manner above the doped layer with dopants and unfavorable crystallinity and roughness, so as to recover and enhance crystallinity and roughness of the epitaxy layer; thereafter, another doped layer with the dopant is grown in an epitaxial manner. The base layers (having no dopant) and the doped layers (having dopants) are alternately grown in an epitaxial manner according to the disclosure; that is, the dopants are doped into the buffer stack structure in a non-continuous manner, such that the breakdown voltage of the semiconductor device can be raised (due to the arrangement of the doped layers with the dopants), and that the resultant semiconductor device can have favorable crystallinity and roughness (due to the arrangement of the base layers having no dopant).

Besides, in the semiconductor device provided herein, the base layers having no dopant are positioned between the doped layers having the dopants, so as to prevent the buffer stack structure from being completely formed by the doped layers with the dopants, i.e., the dopants are doped into the buffer stack structure in a non-continuous manner. As such, the issue of bowing of the entire semiconductor device can be resolved to a greater extent. Hence, in the disclosure, the base layers (having no dopant) and the doped layers (having dopants) are alternately grown in an epitaxial manner, such that the breakdown voltage of the semiconductor device can be raised, and that the issue of bowing of the entire semiconductor device can be resolved. As a result, in the subsequent cooling process following the epitaxial process, the semiconductor device is neither cracked nor broken due to the issue of bowing.

Several exemplary embodiments accompanied with figures are described in detail below to further describe the disclosure in details. It should be understood, however, that the above may not contain all of the aspects and embodiments of the disclosure and may not mean to be limiting or restrictive in any manner, and that the disclosure as disclosed herein is and will be understood by those of ordinary skill in the art to encompass obvious improvements and modifications thereto.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view of a semiconductor device according to an embodiment of the disclosure.

FIG. 2 to FIG. 4 schematically illustrate variations in concentrations of dopants in the semiconductor device provided in the disclosure.

FIG. 5 is a schematic cross-sectional view of a semiconductor device according to another embodiment of the disclosure.

FIG. 6 is a schematic cross-sectional view of a semiconductor device according to another embodiment of the disclosure.

### DETAILED DESCRIPTION OF DISCLOSED EMBODIMENTS

The foregoing description of the embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated.

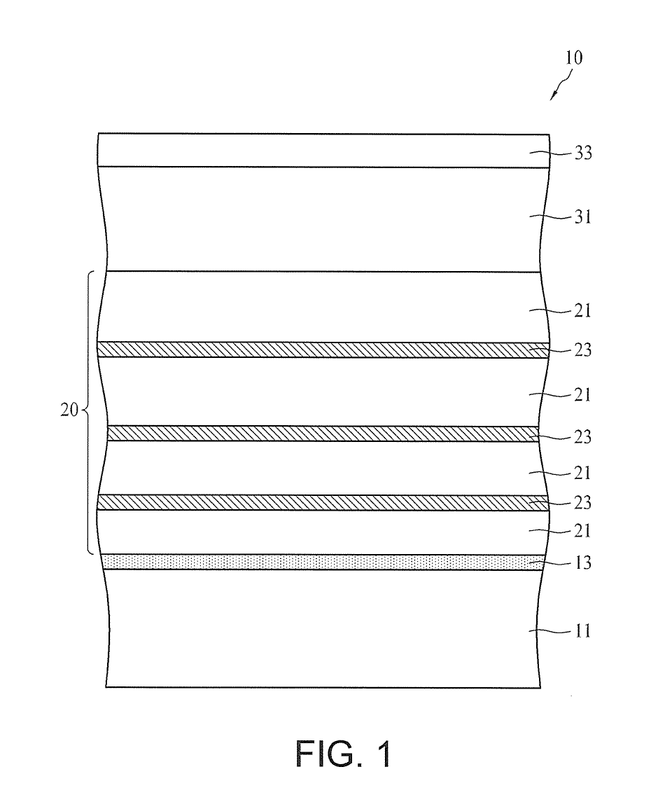

FIG. 1 is a cross-sectional view of a semiconductor device 10 according to an embodiment of the disclosure. In an embodiment of the disclosure, the semiconductor device 10 includes a substrate 11. The substrate 11 is a silicon substrate or a substrate having a silicon surface, such as Si(111), Si(100), Si(110), a textured Si surface, silicon on insulation (SOI), silicon on sapphire (SOS), and a silicon wafer bonded to other materials (AlN, diamond, or any other polycrystalline material). A substrate that can be applied to replace the Si substrate includes a SiC substrate, a sapphire substrate, a GaN substrate, and a gallium arsenide (GaAs) substrate. The substrate 11 may be a half-insulating substrate or a conductive substrate.

The semiconductor device 10 includes an initial layer 13 arranged on the substrate 11, and the initial layer 13 includes AlN. In an exemplary embodiment of the disclosure, the initial layer 13 is grown on the Si substrate having an upper surface of (111) plane in an epitaxial manner, and the thickness of the initial layer 13 is about 200 nm. During the epitaxial growth of the AlN, a mixture having trimethyl amine (TMA) and ammonia (NH₃) is applied as a reactive gas to form the initial layer 13 on the Si substrate. A concentration of carbon in the initial layer 13 is substantially lower than 1E16/cm³.

The semiconductor device 10 includes a buffer stack structure 20 arranged on the initial layer 13. In an embodiment of the disclosure, the semiconductor device 10 further includes at least one doped layer 23 arranged between two adjacent base layers 21. In an embodiment of the disclosure, the buffer stack structure 20 includes a plurality of base layers 21 and a plurality of doped layers 23, and the doped layers 23 and the base layers 21 are alternately stacked on the initial layer 13. In an exemplary embodiment of the disclosure, the base layers 21 include AlGaN, and the doped layers 23 include AlGaN or BAlGaN. The base layers 21 do not contain carbon substantially, and dopants in the doped layers 23 include carbon or iron. In an exemplary embodiment of the disclosure, the doped layers 23 may be C—AlGaN, C—BAlGaN, Fe—AlGaN, or Fe—BAlGaN.

In an exemplary embodiment of the disclosure, a thickness of each doped layer 23 is between 10 angstroms and 1 micrometer, and a ratio of the thickness of each doped layer 23 to a thickness of each base layer 21 is between 0.001 and 1.0. In an exemplary embodiment of the disclosure, a concentration of the dopants in each doped layer 23 is between 1E18/cm³ and 1E20/cm³, and a concentration of dopants in each base layer 21 is lower than 1E18/cm³

In an exemplary embodiment of the disclosure, the buffer stack structure 20 includes four base layers 21. Concentrations of Al in the base layers 21 from bottom to top are x1, x2, x3, and x4, respectively, concentrations of Ga in the base layers 21 from bottom to top are 1-x1, 1-x2, 1-x3, and 1-x4, respectively, and x1>x2>x3>x4. That is, the concentrations of Al in the base layers 21 of the buffer stack structure 20 gradually decrease from bottom to top, and the concentrations of Ga in the base layers 21 of the buffer stack structure 20 gradually increase from bottom to top.

In an exemplary embodiment of the disclosure, concentrations of Al in the doped layers 23 from bottom to top are y1, y2, and y3, respectively. Here, y1=y2=y3, y1≠y2≠y3, y1>y2>y3, or y1<y2<y3. In an exemplary embodiment of the disclosure, x4<y3<x3<y2<x2<y1<x1.

In an embodiment of the disclosure, the buffer stack structure 20 includes four base layers 21 and three doped layers 23. Thicknesses of the four base layers 21 from bottom to top are da1, da2, da3, and da4, respectively. Here, da1=da2=da3=da4, da1≠da2≠da3≠da4, da1>da2>da3>da4, or da1<da2<da3<da4. Thicknesses of the three doped layers 23 from bottom to top are dc1, dc2, and dc3, respectively. Here, dc1=dc2=dc3, dc1≠dc2≠dc3, dc1>dc2>dc3, or dc1<dc2<dc3.

The semiconductor device 10 includes an electron transport layer 31 and an electron supply layer 33 arranged on the buffer stack structure 20. In the semiconductor device 10, 2 DEG is generated around the boundary between the electron transport layer 31 and the electron supply layer 33. Here, 2 DEG is generated in the semiconductor device 10 due to spontaneous polarization and piezoelectric polarization, which results from the fact that the compound semiconductor (GaN) of the electron transport layer 31 and the compound semiconductor (AlGaN) of the electron supply layer 33 are made of hetero materials.

In an exemplary embodiment of the disclosure, the base layer 21 (having no dopant) at the bottom of the buffer stack structure 20 is in contact with the initial layer 13, and the base layer 21 (having no dopant) at the top of the buffer stack structure 20 is in contact with the electron transport layer 31. That is, the doped layers 23 having the dopants in the buffer stack structure 20 of the semiconductor device 10 are neither in contact with the initial layer 13 nor in contact with the electron transport layer 31.

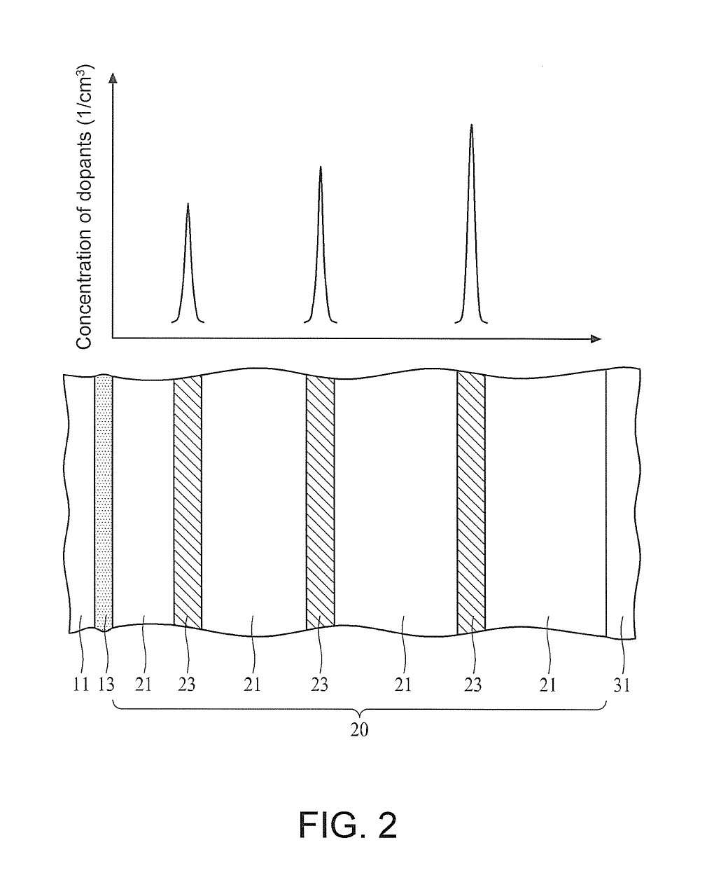

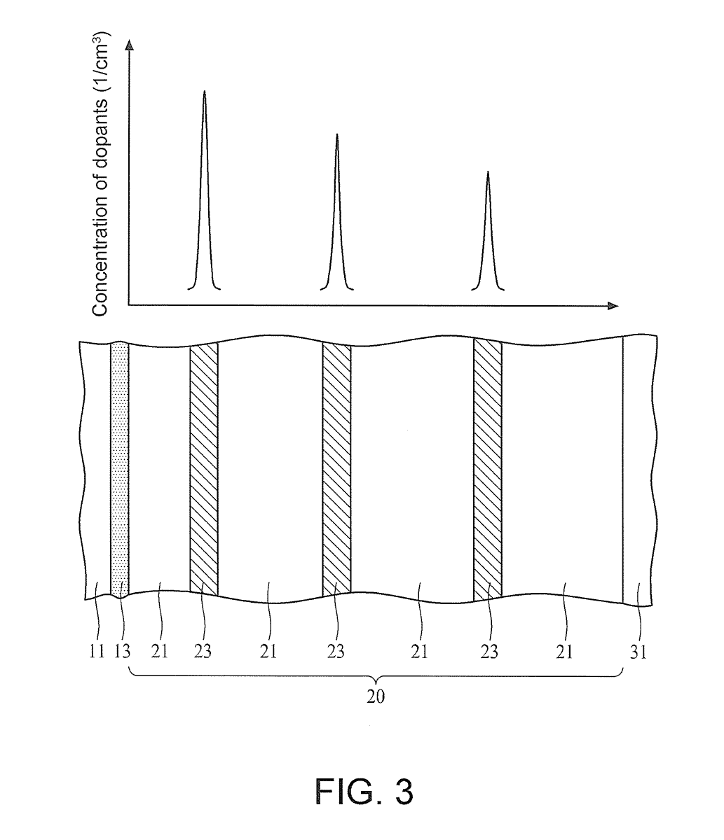

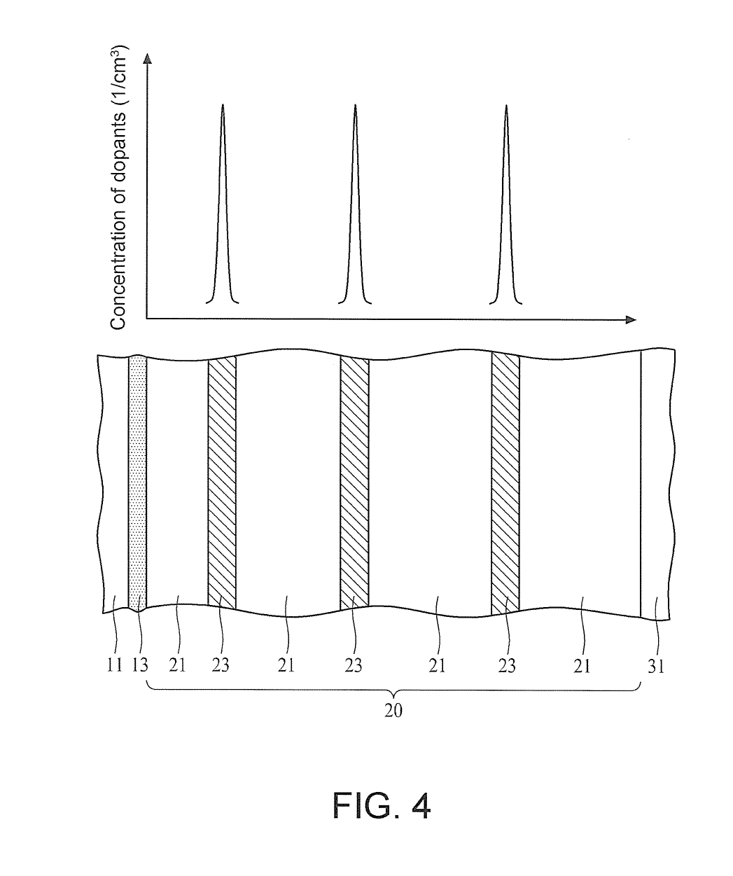

FIG. 2 to FIG. 4 schematically illustrate variations in concentrations of dopants in the semiconductor device 10 provided in the disclosure. In an exemplary embodiment of the disclosure, a concentration of the dopants in the buffer stack structure 20 varies in a non-continuous manner, e.g., in a δ-like manner, as shown in FIG. 2 to FIG. 4. In an exemplary embodiment of the disclosure, the concentration of dopants in the three doped layers 23 in the buffer stack structure 20 may gradually increase (as shown in FIG. 2), gradually decrease (as shown in FIG. 3), or remain unchanged substantially (as shown in FIG. 4). In an exemplary embodiment of the disclosure, the concentration of dopants in the doped layer 23 is higher than a concentration of dopants in each base layer 21, i.e., the concentration of the dopants in the buffer stack structure 20 increases from the base layer 21 to the doped layer 23 and decreases from the doped layer 23 to the base layer 21.

In the disclosure, the doped layer 23 with the dopants is inserted into the buffer stack structure 20 of the semiconductor device 10, so as to reduce the conductivity of the buffer stack structure 20 (i.e., enhance the degree of insulation of the buffer stack structure 20) and further raise the breakdown voltage of the semiconductor device 10 effectively. Compared to the base layers 21 having no dopant, the doped layer 23 with the dopants has unfavorable crystallinity and roughness. Besides, the doped layer 23 having the dopants leads to the issue of bowing of the entire semiconductor device 10. Hence, the buffer stack structure of the semiconductor device should not be completely made of the doped layer with the dopants.

According to the related art, dopants are continuously doped into the entire buffer layer made of AlGaN, which deteriorates crystallinity and roughness and leads to the issue of bowing of the entire semiconductor device. By contrast, in the semiconductor device 10 provided herein, the base layers 21 having no dopants are grown in an epitaxial manner above the doped layer 23 with the dopants, so as to recover crystallinity and roughness of the epitaxy layer (the base layers 21 has no dopants, and thus the crystallinity and roughness of the base layers 21 are relatively satisfactory). More specifically, the base layers 21 having no dopants are grown in an epitaxial manner above the doped layer 23 with dopants and unfavorable crystallinity and roughness, so as to recover and enhance crystallinity and roughness of the epitaxy layer; thereafter, another doped layer 23 with the dopant is grown in an epitaxial manner. The base layers 21 (having no dopant) and the doped layers 23 (having dopants) are alternately grown in an epitaxial manner according to the disclosure; that is, the dopants are doped into the buffer stack structure 20 in a non-continuous manner, such that the breakdown voltage of the semiconductor device 10 can be raised (due to the arrangement of the doped layers 23 with the dopants), and that the resultant semiconductor device 10 can have favorable crystallinity and roughness (due to the arrangement of the base layers having no dopant).

Besides, the base layer 21 having no dopant is positioned between the doped layers 23 having the dopants, so as to prevent the buffer stack structure 20 from being completely formed by the doped layers 23 with the dopants, i.e., the dopants are doped into the buffer stack structure 20 in a non-continuous manner. As such, the issue of bowing of the entire semiconductor device 10 can be resolved to a greater extent. Hence, in the disclosure, the base layers 21 (having no dopant) and the doped layers 23 (having dopants) are alternately grown in an epitaxial manner, such that the breakdown voltage of the semiconductor device 10 can be raised, and that the issue of bowing of the entire semiconductor device 10 can be resolved. As a result, in the subsequent cooling process following the epitaxial process, the semiconductor device 10 is neither cracked nor broken due to the issue of bowing.

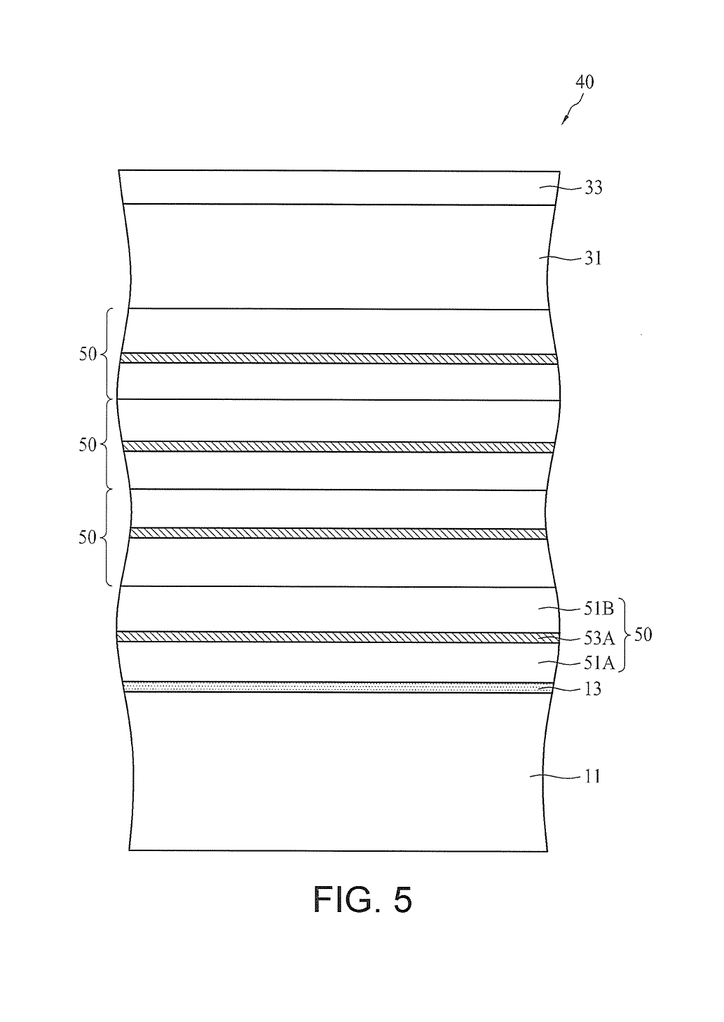

FIG. 5 is a schematic cross-sectional view of a semiconductor device 40 according to another embodiment of the disclosure. The same technical contents in the embodiment shown in FIG. 5 and in the semiconductor device 10 shown in FIG. 1 will not be further explained hereinafter. In the present embodiment of the disclosure, the semiconductor device 40 may include a plurality of buffer stack structures 50. In an embodiment of the disclosure, at least one buffer stack structure 50 includes a first base layer 51A, a first doped layer 53A, and a second base layer 51B. The first doped layer 53A is positioned between the first base layer 51A and the second base layer 51B, i.e., the first doped layer 53A is located inside the buffer stack structure 50.

Compared to the semiconductor device 10 shown in FIG. 1, i.e., the buffer stack structure 20 is achieved by applying the structure of alternately arranged film layers (base layers 21 and doped layers 23), the semiconductor device 40 shown in FIG. 5 has the buffer stack structures 50 with sandwich-like film-layer structure. In an exemplary embodiment of the disclosure, each of the buffer stack structures 50 includes a first base layer 51A, a first doped layer 53A, and a second base layer 51B. The first base layer 51A and the second base layer 51B include AlGaN, and the first doped layer 53A includes AlGaN or BAlGaN. The first doped layer 53A is positioned between the first base layer 51A and the second base layer 51B. A concentration of Al of the first base layer 51A and a concentration of Al of the second base layer 51B are substantially the same. The first base layer 51A and the second base layer 51B do not contain carbon substantially, and dopants in the first doped layer 53A include carbon or iron. In an exemplary embodiment of the disclosure, the first doped layer 53A may be C—AlGaN, C—BAlGaN, Fe—AlGaN, or Fe—BAlGaN.

In an exemplary embodiment of the disclosure, a thickness of the first doped layer 53A of the buffer stack structure 50 is between 10 angstroms and 1 micrometer, and a ratio of the thickness of the first doped layer 53A to a thickness of the first base layer MA (or the second base layer 51B) is between 0.001 and 1.0. In an exemplary embodiment of the disclosure, a concentration of the dopants in the first doped layer 53A is between 1E18/cm³ and 1E20/cm³, and a concentration of dopants in the first base layer 51A (or the second base layer 51B) is lower than 1E18/cm³.

In an exemplary embodiment of the disclosure, the semiconductor device 40 includes four buffer stack structures 50. The compositions of the first base layer 51A and the second base layer 51B are substantially the same. Concentrations of Al in the buffer stacked structures 50 from bottom to top are x1, x2, x3, and x4, respectively, concentrations of Ga in the buffer stacked structures 50 from bottom to top are 1-x1, 1-x2, 1-x3, and 1-x4, respectively, and x1>x2>x3>x4. That is, the concentrations of Al in the first base layers 51A (or the second base layers 51B) of the four buffer stack structures 50 gradually decrease from bottom to top, and the concentrations of Ga in the base layers 51A (or the second base layers 51B) of the four buffer stack structures 50 gradually increase from bottom to top. In an exemplary embodiment of the disclosure, concentrations of Al in the four first doped layers 53A from bottom to top are y1, y2, y3, and y4, respectively. Here, y1=y2=y3=y4, y1≠y2≠y3≠y4, y1>y2>y3>y4, or y1<y2<y3<y4.

In an exemplary embodiment of the disclosure, the semiconductor device 40 includes four buffer stack structures 50. Thicknesses of the first and second base layers 51A and 51B are substantially the same. The thicknesses of the first base layers 51A (or the second base layers 51B) from bottom to top are da1, da2, da3, and da4, respectively. Here, da1=da2=da3=da4, da1≠da2≠da3≠da4, da1>da2>da3>da4, or da1<da2<da3<da4. Thicknesses of the four first doped layers 53A from bottom to top are dc1, dc2, dc3, and dc4, respectively. Here, dc1=dc2=dc3=dc4, dc1≠dc2≠dc3≠dc4, dc1>dc2>dc3>dc4, or dc1<dc2<dc3<dc4.

In an exemplary embodiment of the disclosure, the first base layer 51A (having no dopant) at the bottom of the buffer stack structure 50 is in contact with the initial layer 13, and the second base layer 51B (having no dopant) at the top of the buffer stack structure 50 is in contact with the electron transport layer 31. That is, the first doped layers 53A having the dopants in the buffer stack structures 50 of the semiconductor device 40 are neither in contact with the initial layer 13 nor in contact with the electron transport layer 31.

In an exemplary embodiment of the disclosure, a concentration of the dopants in the plurality of buffer stack structures 50 varies in a non-continuous manner, e.g., in a δ-like manner, as shown in FIG. 2 to FIG. 4. In an exemplary embodiment of the disclosure, the concentration of dopants in the four first doped layers 53A in the semiconductor device 40 may gradually increase (as shown in FIG. 2), gradually decrease (as shown in FIG. 3), or remain unchanged substantially (as shown in FIG. 4). In an exemplary embodiment of the disclosure, the concentration of dopants in the first doped layer 53A is higher than a concentration of dopants in the first base layer 51A (or the second base layer 51B), i.e., the concentration of the dopants increases from the first base layer 51A to the first doped layer 53A and decreases from the first doped layer 53A to the second base layer 51B.

In the disclosure, the first doped layer 53A with the dopants is inserted into the buffer stack structure 50 of the semiconductor device 40, so as to reduce the conductivity of the buffer stack structure 50 (i.e., enhance the degree of insulation of the buffer stack structure 50) and further raise the breakdown voltage of the semiconductor device 40 effectively. Compared to the first base layer 51A (or the second base layer 51B) having no dopant, the first doped layer 53A with the dopants has unfavorable crystallinity and roughness. Besides, the first doped layer 53A having the dopants leads to the issue of bowing of the entire semiconductor device 40.

According to the related art, dopants are continuously doped into the entire buffer layer made of AlGaN, which deteriorates crystallinity and roughness and leads to the issue of bowing of the entire semiconductor device. By contrast, in the semiconductor device 40 provided herein, the first base layer 51A and the second base layer 51B having no dopants are respectively grown in an epitaxial manner below and above the first doped layer 53A with the dopants, so as to recover crystallinity and reduce roughness of the epitaxy layer (the first base layer 51A and the second base layer 51B have no dopants, and thus the crystallinity and roughness of the first and second base layers 51A and 51B are relatively satisfactory). More specifically, the first and second base layers 51A and 51B having no dopants are grown in an epitaxial manner below and above the first doped layer 53A with dopants and unfavorable crystallinity and roughness, so as to recover and enhance crystallinity and roughness of the epitaxy layer; thereafter, another first doped layer 53A with the dopant is grown in an epitaxial manner. Layers having no dopant (the first and second base layers 51A and 51B) and the first doped layer 53A (having dopants) are alternately grown in an epitaxial manner according to the disclosure, such that the breakdown voltage of the semiconductor device 40 can be raised (due to the arrangement of the first doped layer 53A with the dopants), and that the resultant semiconductor device 40 can have favorable crystallinity and roughness (due to the arrangement of the first and second base layers 51A and 51B having no dopant).

Besides, in the semiconductor device 40 provided herein, the first base layer 51A and the second base layer 51B are respectively grown in an epitaxial manner below and above the first doped layer 53A having the dopants, so as to prevent the buffer stack structure 50 from being completely formed by the first doped layer 53A with the dopants, i.e., the dopants are doped into the buffer stack structure 50 in a non-continuous manner. As such, the issue of bowing of the entire semiconductor device 40 can be resolved to a greater extent. Hence, in the disclosure, layers having no dopant (the first and second base layers 51A and 51B) and the first doped layer 53A (having dopants) are alternately grown in an epitaxial manner, such that the breakdown voltage of the semiconductor device 40 can be raised, and that the issue of bowing of the entire semiconductor device 40 can be resolved. As a result, in the subsequent cooling process following the epitaxial process, the semiconductor device 40 is neither cracked nor broken due to the issue of bowing.

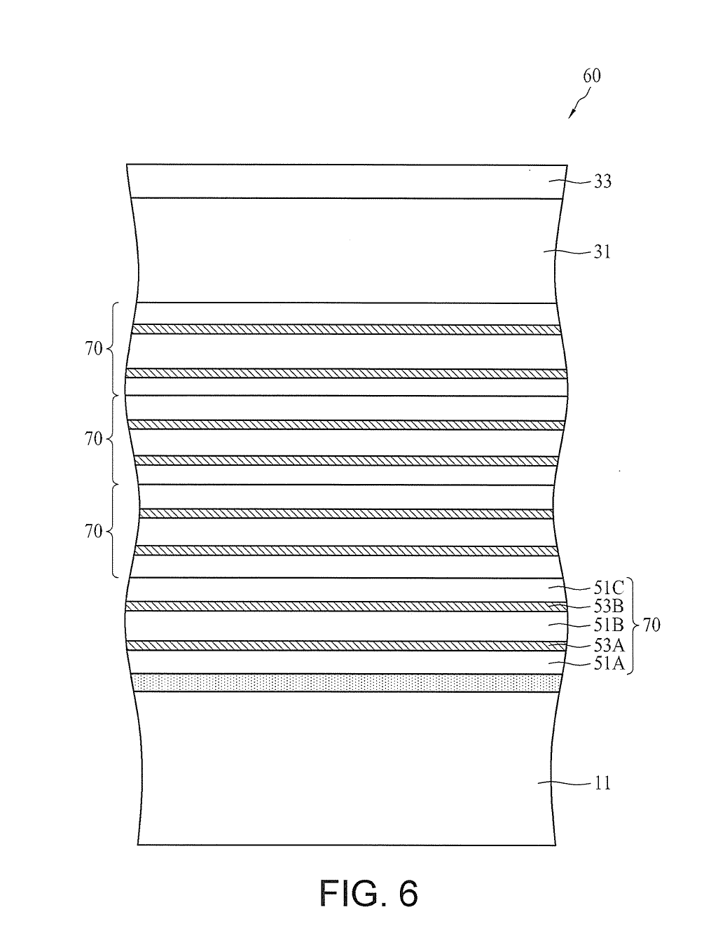

FIG. 6 is a schematic cross-sectional view of a semiconductor device 60 according to another embodiment of the disclosure. The same technical contents in the embodiment shown in FIG. 6 and in the semiconductor device 10 and the semiconductor device 40 respectively shown in FIG. 1 and FIG. 5 will not be further explained hereinafter. Compared to the semiconductor device 40 shown in FIG. 5 having the buffer stack structures 50 with a plurality of sandwich-like film-layer structures, the semiconductor device 60 shown in FIG. 6 has the buffer stack structure 70 with a plurality of five-layer structures.

In an embodiment of the disclosure, the buffer stack structure 70 of the semiconductor device 60 further includes a second doped layer 53B and a third base layer 51C besides a first base layer 51A, a first doped layer 53A, and a second base layer 51B. The second doped layer 53B is positioned between the second base layer 51B and the third base layer 51C.

In an exemplary embodiment of the disclosure, the third base layer 51C includes AlGaN, and the second doped layer 51B includes AlGaN or BAlGaN. In an exemplary embodiment of the disclosure, the dopants in the second doped layer 51B include carbon or iron, and the second doped layer 51B may be C—AlGaN, C—BAlGaN, Fe—AlGaN, or Fe—BAlGaN. In each buffer stack structure 70, concentrations of Al in the first base layer 51A, the second base layer 51B, and the third base layer 51C are substantially the same and do not contain carbon substantially.

To sum up, in the semiconductor device 60 depicted in FIG. 6, two doped layers are inserted between the base layers composed of AlGaN, so as to form the buffer stack structure. The concentrations of dopants in the two doped layers may the same or different. By contrast, in the semiconductor device 40 depicted in FIG. 6, one doped layer is inserted between the base layers composed of AlGaN, so as to form the buffer stack structure. Alternatively, in the semiconductor device 60 depicted in FIG. 6, three or more doped layers may be inserted between the base layers composed of AlGaN, so as to form the buffer stack structure.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents. Moreover, no element and component in the present disclosure is intended to be dedicated to the public regardless of whether the element or component is explicitly recited in the following claims.

What is claimed is:

1. A semiconductor device comprising:
a substrate;
an initial layer located on the substrate, the initial layer comprising aluminum nitride; and
a buffer stack structure located on the initial layer, the buffer stack structure comprising a plurality of base layers and at least one doped layer positioned between two adjacent base layers, each of the base layers comprising aluminum gallium nitride, the at least one doped layer comprising aluminum gallium nitride or boron aluminum gallium nitride,
wherein in the buffer stack structure, concentrations of aluminum in the base layers gradually decrease, concentrations of gallium in the base layers gradually increase, the base layers do not contain carbon substantially, and dopants in the at least one doped layer comprise carbon or iron.

2. The semiconductor device of claim 1, wherein the number of the at least one doped layer is plural, and the doped layers and the base layers are alternately stacked on the initial layer.

3. The semiconductor device of claim 1, wherein a thickness of each of the at least one doped layer is between 10 angstroms and 1 micrometer.

4. The semiconductor device of claim 1, wherein a ratio of a thickness of each of the at least one doped layer to a thickness of each of the base layers is between 0.001 and 1.0.

5. The semiconductor device of claim 1, wherein a concentration of the dopants in each of the at least one doped layer is between 1E18/cm³ and 1E20/cm³.

6. The semiconductor device of claim 1, wherein a concentration of dopants in each of the base layers is lower than 1E18/cm³.

7. The semiconductor device of claim 1, wherein a concentration of the dopants in the buffer stack structure varies in a wave-like manner.

8. The semiconductor device of claim 1, wherein a concentration of the dopants in the buffer stack structure varies in a non-continuous manner.

9. The semiconductor device of claim 1, wherein a concentration of the dopants in the buffer stack structure increases from the base layers to the at least one doped layer.

10. The semiconductor device of claim 1, wherein a concentration of the dopants in the buffer stack structure decreases from the at least one doped layer to the base layers.

11. The semiconductor device of claim 1, wherein one of the base layers in the buffer stack structure is in contact with the initial layer.

12. The semiconductor device of claim 1, further comprising an electron transport layer located on the buffer stack structure, and one of the base layers in the buffer stack structure is in contact with the electron transport layer.

13. A semiconductor device comprising:
a substrate;
an initial layer located on the substrate, the initial layer comprising aluminum nitride; and
a plurality of buffer stack structures located on the initial layer;
wherein at least one of the buffer stack structures comprises a first base layer, a first doped layer, and a second base layer, a concentration of aluminum of the first base layer and a concentration of aluminum of the second base layer are substantially the same, and the first doped layer is positioned between the first base layer and the second base layer;
wherein the first base layer and the second base layer comprise aluminum gallium nitride, the first doped layer comprises aluminum gallium nitride or boron aluminum gallium nitride, dopants in the first doped layer comprise carbon or iron, and the first base layer and the second base layer do not contain carbon substantially.

14. The semiconductor device of claim 13, wherein each of the buffer stack structures comprises the first doped layer positioned between the first base layer and the second base layer.

15. The semiconductor device of claim 13, wherein a thickness of the first doped layer is between 10 angstroms and 1 micrometer.

16. The semiconductor device of claim 13, wherein a ratio of a thickness of the first doped layer to a thickness of the first base layer is between 0.001 and 1.0.

17. The semiconductor device of claim 13, wherein a ratio of a thickness of the first doped layer to a thickness of the second base layer is between 0.001 and 1.0.

18. The semiconductor device of claim 13, wherein a concentration of the dopants in the first doped layer is between 1E18/cm³ and 1E20/cm³.

19. The semiconductor device of claim 13, wherein a concentration of carbon in the first and second base layers is lower than 1E18/cm³.

20. The semiconductor device of claim 13, wherein in the buffer stack structures, concentrations of aluminum of the first and second base layers gradually decrease, and concentrations of gallium of the first and second base layers gradually increase.

21. The semiconductor device of claim 13, wherein concentrations of the dopants in the buffer stack structures vary in a wave-like manner.

22. The semiconductor device of claim 13, wherein concentrations of the dopants in the buffer stack structures vary in a non-continuous manner.

23. The semiconductor device of claim 13, wherein a concentration of the dopants in the at least one of the buffer stack structures increases from the first base layer to the first doped layer.

24. The semiconductor device of claim 13, wherein a concentration of the dopants in the at least one of the buffer stack structures decreases from the first doped layer to the second base layer.

25. The semiconductor device of claim 13, wherein the first base layer in the at least one of the buffer stack structures is in contact with the initial layer.

26. The semiconductor device of claim 13, further comprising an electron transport layer located on the at least one of the buffer stack structures, and the second base layer in the at least one of the buffer stack structures is in contact with the electron transport layer.

27. The semiconductor device of claim 13, wherein the at least one of the buffer stack structures further comprises a second doped layer and a third base layer, and the second doped layer is positioned between the second base layer and the third base layer.

28. The semiconductor device of claim 27, wherein the second doped layer comprises aluminum gallium nitride or boron aluminum gallium nitride, and the third base layer does not contain carbon substantially.

29. The semiconductor device of claim 27, wherein in each of the at least one of the buffer stack structures, concentrations of aluminum in the first base layer, the second base layer, and the third base layer are substantially the same.
